(19) United States
(12) Patent Application Publication
(10) Pub. No.: US 2026/0269599 A1
(43) Pub. Date: Sep. 10, 2026

(54) ARC FAULT PROTECTION FOR VEHICLES

(71) Applicant: GM Global Technology Operations LLC, Detroit, MI (US)

(72) Inventors: James MORRISON, Wheatley (CA); Mohamed Ahmed Kamel AHMED, Birmingham, MI (US); Lyall Kenneth WINGER, Waterloo (CA); Suresh GOPALAKRISHNAN, Troy, MI (US)

(21) Appl. No.: 19/071,896

(22) Filed: Mar. 6, 2025

(51) Int. Cl. H02H 7/20; G01R 31/00; G01R 31/12; H02H 9/02

(52) U.S. Cl. CPC H02H 7/20; G01R 31/007; G01R 31/1272; H02H 9/025

(57) ABSTRACT

An example arc fault detection system for vehicles includes at least one vehicle battery, at least one vehicle electrical load, a power distribution circuit power distribution circuit including at least one switch, and a vehicle control module configured to periodically compare a change in the current value to a specified current change threshold value, according to first and second first time periods, and increase a first or second count values respectively each time the change in the current value exceeds the specified current change threshold value according to the first time period or the second time period, compare the first and second count values to a specified arc onset threshold, and open the at least one switch in response to the first count value and the second count value reaching or exceeding the specified arc onset threshold, to mitigate the arc fault.

### INTRODCUTION

The information provided in this section is for the purpose of generally presenting the context of the disclosure. Work of the presently named inventors, to the extent it is described in this section, as well as aspects of the description that may not otherwise qualify as prior art at the time of filing, are neither expressly nor impliedly admitted as prior art against the present disclosure.

The present disclosure generally relates to arc fault detection for vehicles, including systems and methods for detecting an onset of an arc fault to mitigate the arc fault.

Due to the increased power demands being placed on vehicles, automotive electrical systems are being built that provide high voltages. In many vehicles, a +48 volt battery system is being used to provide higher electrical power while also improving the electrical efficiency of the vehicle.

### SUMMARY

An example arc fault detection system for vehicles includes at least one vehicle battery, at least one vehicle electrical load, a power distribution circuit configured to supply power from the at least one vehicle battery to the at least one vehicle electrical load, the power distribution circuit including at least one switch, a sensor configured to detect a current value through the power distribution circuit, and a vehicle control module configured to periodically compare a change in the current value to a specified current change threshold value, according to a first time period, and increase a first count value each time the change in the current value exceeds the specified current change threshold value according to the first time period, periodically compare the change in the current value to the specified current change threshold value, according to a second time period different than the first time period, and increase a second count value each time the change in the current value exceeds the specified current change threshold value according to the second time period, compare the first count value and the second count value to a specified arc onset threshold indicative of an onset of an arc flash phase of an arc fault, and open the at least one switch of the power distribution circuit in response to the first count value and the second count value reaching or exceeding the specified arc onset threshold, to mitigate the arc fault.

In some examples, the at least one switch comprises a field-effect transistor. In some examples, the vehicle control module is configured to close the field-effect transistor after an end of the arc fault to reset at least a portion of the power distribution circuit.

In some examples, the vehicle control module is configured to obtain a current signature of the at least one vehicle electrical load, compare the current signature to a stored transient load event signature indicative of occurrence of a transient power event for the at least one vehicle electrical load, and inhibit arc fault mitigation, in response to a match between the current signature and the stored transient load event signature.

In some examples, the stored transient load event signature corresponds to a high-frequency load pattern. In some examples, the vehicle control module is configured to detect a fault condition of the at least one vehicle electrical load, and inhibit arc fault mitigation, in response to detecting the fault condition of the at least one vehicle electrical load.

In some examples, multiple electrical loads are each coupled to receive power from the at least one vehicle battery via the power distribution circuit, and the vehicle control module is configured to obtain a current signature for each of the multiple electrical loads, and inhibit arc fault mitigation, in response to the current signature for each of the multiple electrical loads being a common current signature indicative of a common transient condition across the multiple electrical loads.

In some examples, the at least one vehicle electrical load comprises a resistive electrical load, and the specified current change threshold value defines an amount of decrease in the current value from a steady-state current.

In some examples, the at least one vehicle electrical load receives comprises a power converter, and the specified current change threshold value defines an amount of increase in the current value from a steady-state current.

In some examples, the vehicle control module is configured to periodically compare the change in the current value to the specified current change threshold value, according to a third time period different than the first time period and the second time period, and increase a third count value each time the change in the current value exceeds the specified current change threshold value according to the third time period, comparing includes comparing the first count value, the second count value and the third count value to the specified arc onset threshold, and opening incudes opening the at least one switch in response to the first count value, the second count value and the third count value reaching or exceeding the specified arc onset threshold.

In some examples, the first time period is one nanosecond, the second time period is ten nanoseconds, and the third time period is one hundred nanoseconds. In some examples, the specified current change threshold value is at least two Amps. In some examples, the at least one vehicle battery is configured to output a voltage of at least twenty Volts.

In some examples, the vehicle control module is configured to open the at least one switch without executing a Fast Fourier Transform (FFT) analysis on the current value.

An example method of arc fault detection system for vehicles includes supplying power from at least one vehicle battery to at least one vehicle electrical load via a power distribution circuit, the power distribution circuit including at least one switch, detecting, by a current sensor, a current value through the power distribution circuit, periodically comparing, by a vehicle control module, a change in a current value to a specified current change threshold value, according to a first time period, and increase a first count value each time the change in the current value exceeds the specified current change threshold value according to the first time period, periodically comparing the change in the current value to the specified current change threshold value, according to a second time period different than the first time period, and increase a second count value each time the change in the current value exceeds the specified current change threshold value according to the second time period, comparing the first count value and the second count value to a specified arc onset threshold indicative of an onset of an arc flash phase of an arc fault, and opening the at least one switch of the power distribution circuit in response to the first count value and the second count value reaching or exceeding the specified arc onset threshold, to mitigate the arc fault.

In some examples, the at least one switch comprises a field-effect transistor. In some examples, the method includes closing the field-effect transistor after to an end of the arc fault to reset at least a portion of the power distribution circuit.

In some examples, the method includes obtaining a current signature of the at least one vehicle electrical load, comparing the current signature to a stored transient load event signature indicative of occurrence of a transient power event for the at least one vehicle electrical load, and inhibiting arc fault mitigation, in response to a match between the current signature and the stored transient load event signature. In some examples, the stored transient load event signature corresponds to at least one of a motor torque event or a motor braking event.

An example arc fault detection system for vehicles includes a power distribution circuit configured to supply power from at least one vehicle battery to at least one vehicle electrical load, the power distribution circuit including at least one switch, a sensor configured to detect a current value through the power distribution circuit, and a vehicle control module configured to periodically compare a change in the current value to a specified current change threshold value, according to a first time period, and increase a first count value each time the change in the current value exceeds the specified current change threshold value according to the first time period, periodically compare the change in the current value to the specified current change threshold value, according to a second time period different than the first time period, and increase a second count value each time the change in the current value exceeds the specified current change threshold value according to the second time period, compare the first count value and the second count value to a specified arc onset threshold indicative of an onset of an arc flash phase of an arc fault, and open the at least one switch of the power distribution circuit in response to the first count value and the second count value reaching or exceeding the specified arc onset threshold, to mitigate the arc fault, without executing a Fast Fourier Transform (FFT) analysis on the current value.

Further areas of applicability of the present disclosure will become apparent from the detailed description, the claims, and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings.

FIG. 1 is a diagram of an example vehicle including a vehicle control module for arc fault detection.

FIG. 2 is a block diagram of an example electrical system of a vehicle.

FIG. 3 is a block diagram of an example arc fault protection device.

FIG. 4 is side view of an example terminal post of a vehicle electrical system.

FIG. 5 is a block diagram of an example power distribution circuit in a vehicle including an electronic switch for arc fault protection.

FIG. 6 is a graph illustrating an example electrical signal of an arc fault in a vehicle electrical system.

FIG. 7 is a graph illustrating another example electrical signal of an arc fault in a vehicle electrical system.

FIG. 8 is a flowchart depicting an example process for detecting and mitigating an arc fault in a vehicle.

In the drawings, reference numbers may be reused to identify similar and/or identical elements.

### DETAILED DESCRIPTION

Some example embodiments may include circuits for arc protection in vehicles. For example, a power net voltage above about 20V can potentially cause the occurrence of an arc fault. Since an arc fault may not result in an over current or an over voltage, it can go undetected by protection devices because it can happen so fast. The arc fault may destroy protection devices that cannot respond fast enough.

In some example embodiments, edge rate detection circuits may be tailored to specific edge rates (e.g., 1ns, 10ns, 50ns, 100ns, etc.) for current or voltage signals in a vehicle electrical system, such as measured signals representing the current passing through a pass transistor of an electronic switch (e.g., eFuse device) in real-time. The edge rates may be configured to facilitate detection of an electrical arc event in the vehicle electrical system, by comparing a histogram of detected current or voltage signal changes to a known event signature.

In some examples, simulations of an expected arc event may be performed using Fast Fourier Transform (FFT) analysis, to determine that the vehicle electrical system signal had significant high-frequency contents that would easily be detected with edge detection circuits. Detection may be implemented based on a measured current waveform, to detect and mitigate both series arc events and parallel arc events. A series arc event may not necessarily be observable when monitoring voltage, depending on where the arc physically occurs relative to the measurement node.

Example detection circuits may provide low-cost arc detection, which may be achieved while avoiding the need for an FFT analysis, and instead implementing the signal processing by using simple edge rate detectors having different edge rates (which may be configurable). Detected changes in the current signal may be accumulated in a histogram, and a simple logical comparison against an "event signature" may produce a desired detection.

When an arc event is detected based on the histogram count threshold or defined event signature, a pass element transistor (e.g., part of the electronic switch eFuse circuit) may be opened to disconnect the power source (e.g., vehicle battery) from the offending circuit. This may extinguish the current electrical arc, and allow the system to ensure future electrical arcs do not form. Due to the simple analog and logic circuits, the silicon area to implement example embodiments may be very small, and may also result in a reduced printed circuit board (PCB) area in the final assembly.

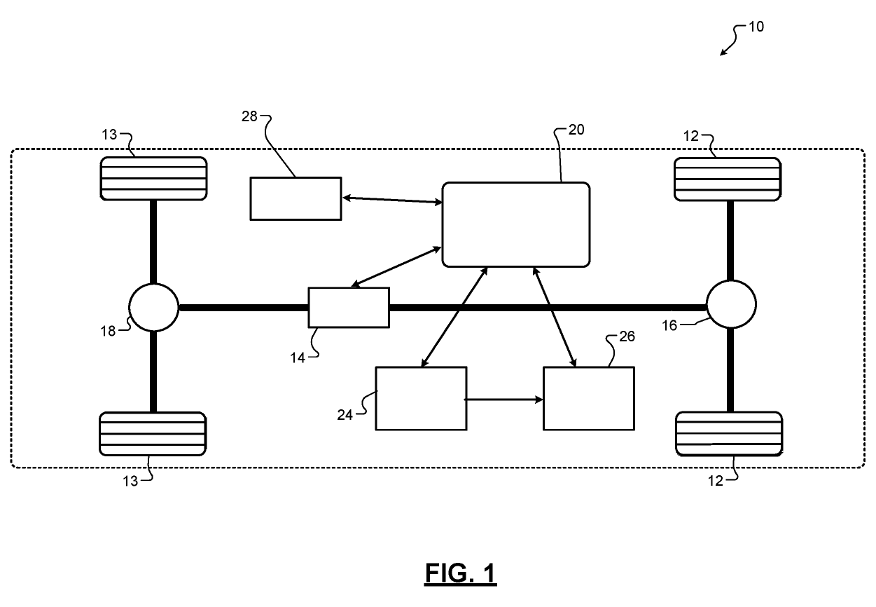

Referring now to FIG. 1, a vehicle 10 includes front wheels 12 and rear wheels 13. In FIG. 1, a drive unit 14 selectively outputs torque to the front wheels 12 and/or the rear wheels 13 via drive lines 16, 18, respectively. The vehicle 10 may include different types of drive units. For example, the vehicle may be an electric vehicle such as a battery electric vehicle (BEV), a hybrid vehicle, or a fuel cell vehicle, a vehicle including an internal combustion engine (ICE), or other type of vehicle.

Some examples of the drive unit 14 may include any suitable electric motor, a power inverter, and a motor controller configured to control power switches within the power inverter to adjust the motor speed and torque during propulsion and/or regeneration. A battery system provides power to or receives power from the electric motor of the drive unit 14 via the power inverter during propulsion or regeneration.

While the vehicle 10 includes one drive unit 14 in FIG. 1, the vehicle 10 may have other configurations. For example, two separate drive units may drive the front wheels 12 and the rear wheels 13, one or more individual drive units may drive individual wheels, etc. As can be appreciated, other vehicle configurations and/or drive units can be used.

The vehicle control module 20 may be configured to control operation of one or more vehicle components, such as the drive unit 14 (e.g., by commanding torque settings of an electric motor of the drive unit 14). The vehicle control module 20 may receive inputs for controlling components of the vehicle, such as signals received from a steering wheel, an acceleration pedal, a brake pedal, etc. The vehicle control module 20 may monitor telematics of the vehicle for safety purposes, such as vehicle speed, vehicle location, vehicle braking and acceleration, etc.

The vehicle control module 20 may receive signals from any suitable components for monitoring one or more aspects of the vehicle, including one or more vehicle sensors (such as cameras, microphones, pressure sensors, steering wheel position sensors, braking sensors, location sensors such as global positioning system (GPS) antennas, wheel height and/or position sensors, accelerometers, etc.). Some sensors may be configured to monitor current motion of the vehicle, acceleration of the vehicle, braking of the vehicle, current steering direction of the vehicle, current height and/or position of one or more wheels, etc.

In some examples, the vehicle 10 may include a front vehicle camera, an optional side vehicle camera, an optional rear vehicle camera, etc. Each camera may include any suitable camera hardware components, image processing capabilities, etc., to capture images of surroundings of the vehicle, such as road features, other vehicles, etc. In some examples, images from vehicle cameras may be used for object detection, automated driving, lane determination, etc. Other example embodiments may include more or less cameras, or cameras at other positions on the vehicle 10. Other systems such as Lidar may be used to determine images or information about the surrounding environment of the vehicle.

The vehicle control module 20 may communicate with another device via a wireless communication interface 28, which may include one or more wireless antennas for transmitting and/or receiving wireless communication signals. For example, the wireless communication interface 28 may communicate via any suitable wireless communication protocols, including but not limited to vehicle-to-everything (V2X) communication, Wi-Fi communication, wireless area network (WAN) communication, cellular communication, personal area network (PAN) communication, short-range wireless communication (e.g., Bluetooth), etc. The wireless communication interface 28 may communicate with a remote computing device over one or more wireless and/or wired networks. Regarding the vehicle-to-vehicle (V2X) communication, the vehicle 10 may include one or more V2X transceivers (e.g., V2X signal transmission and/or reception antennas).

As shown in FIG. 1, the vehicle 10 includes a vehicle battery 24, which is configured to supply power to one or more vehicle electrical loads 26. The vehicle battery 24 may include any suitable vehicle battery modules, such as a series or parallel connected battery cells, etc. The vehicle battery 24 may provide power to the one or more vehicle electrical loads 26 via one or more power distribution circuits. As described further below, the power distribution circuits may include one or more sensors for detecting electrical signals such as current or voltage, and one or more electronic fuse switches for providing arc protection in response to detected arc events (e.g., by opening the electronic switch when an arc event precursor is detected using different edge detection rates on a current signal).

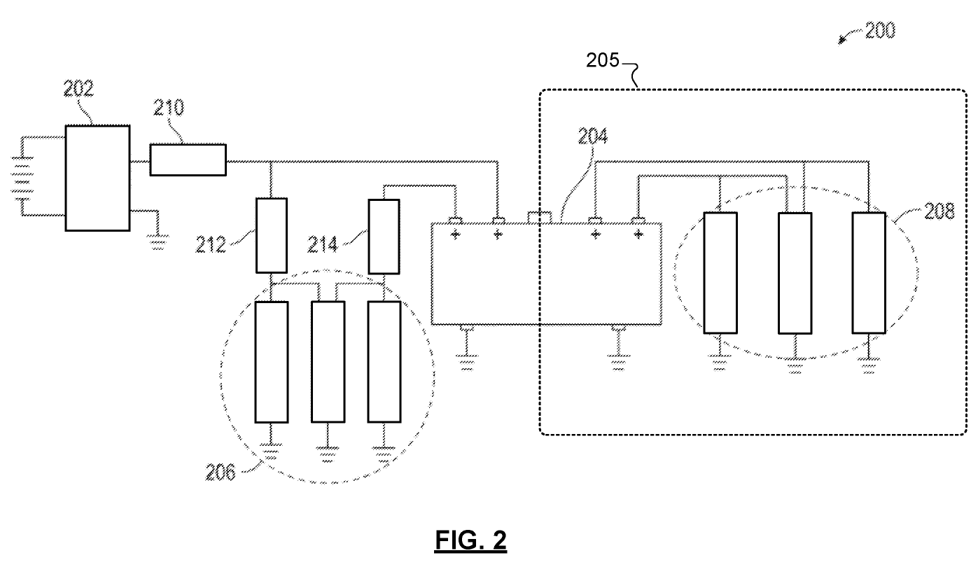

FIG. 2 is a block diagram of an example electrical system 200 of a vehicle. The electrical system 200 may include a high voltage source 202 connected to, for example, a battery management system 204, one or more high voltage loads 206 (e.g., 48V loads), and optionally one or more low voltage loads 208 (e.g., 12V loads).

The high voltage source 202 may be configured to provide high voltage (e.g., +48V or more or less) to the battery management system 204 and to one or more high voltage loads 206 (e.g., 48V loads, or more or less). In some example, the high voltage source may provide an output voltage of at least twenty Volts, as the actual voltage on the power rail may vary over a range.

As shown in FIG. 2, the high voltage source 202 may optionally provide power to a group 205 of low volage loads, such as the low voltage loads 208 (e.g., 12V loads, or more or less). For example, the battery management system 204 may include one or more DC/DC converters, such as a 48V to 12V DC/DC converter The battery management system 204 provides a low voltage (e.g., +12V or more or less) to the low voltage loads 208. In some example embodiments, the electrical system 102 can operate without the high voltage to low voltage DC/DC converters of the battery management system 204.

The electrical system 200 may include various arc fault protection devices for detecting and preventing or mitigating an occurrence of an arc fault. Each arc fault protection device may be a part of the vehicle control module, or in communication with the vehicle control module. The arc fault protection devices may be placed at strategic locations within the electrical system 200.

For illustrative purposes, a first arc fault protection device 210 is located at an output of the high voltage source 202, a second arc fault protection device 212 is located between the high voltage source 202 and the one or more high voltage loads 206, and a third arc fault protection device 214 is located between the high voltage loads 206 and the battery management system 204. Although not shown in FIG. 2 , arc fault protection devices may also be disposed on the low voltage side of the battery management system 204. Each arc fault protection device may be configured to measure a current, filter and process the current to detect an incipient arc fault, and takes measures to mitigate the arc fault once it is detected.

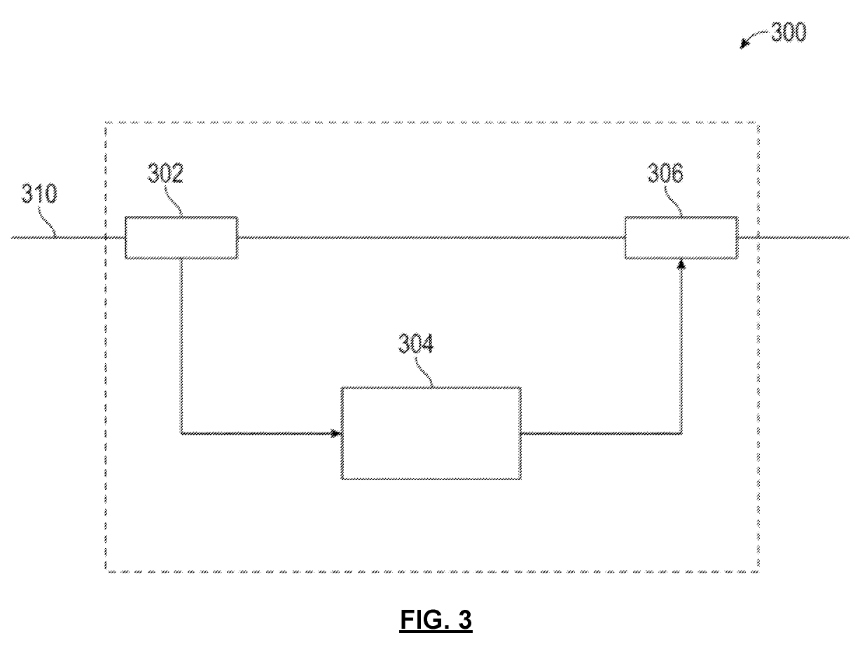

FIG. 3 is a block diagram of an example arc fault protection device 300. The arc fault protection device may include a current sensor 302, an arc fault detector 304 and a switch 306. The current sensor 302 may be configured to measure a current flowing through a branch 310 of the electrical circuit. The current sensor 302 may be a high-bandwidth current sensor. In various example embodiments, the current sensor 302 may be a core-based current sensor, a point field detector, a shunt-based detector, a Rogowski coil-based sensor, etc.

The arc fault detector 304 may include a processor, such as a micro-processor, or other circuitry for evaluating the current and determining an onset of an arc fault from the current. The arc fault detector 304 may open the switch 306 when the evaluation of the current indicates that an arc flash is imminent. In various example embodiments, the switch 306 may be an electronic switch, such as an electrical fuse (eFuse) that operates via various transistors or a mechanical switch in series with a mechanical fuse. The switch306may be a field-effect transistor (FET) or other suitable electronic switch and may be configured to be closed or reset after an arc fault event has been detected and the switch opened (e.g., after the end of the arc fault and a circuit reset).

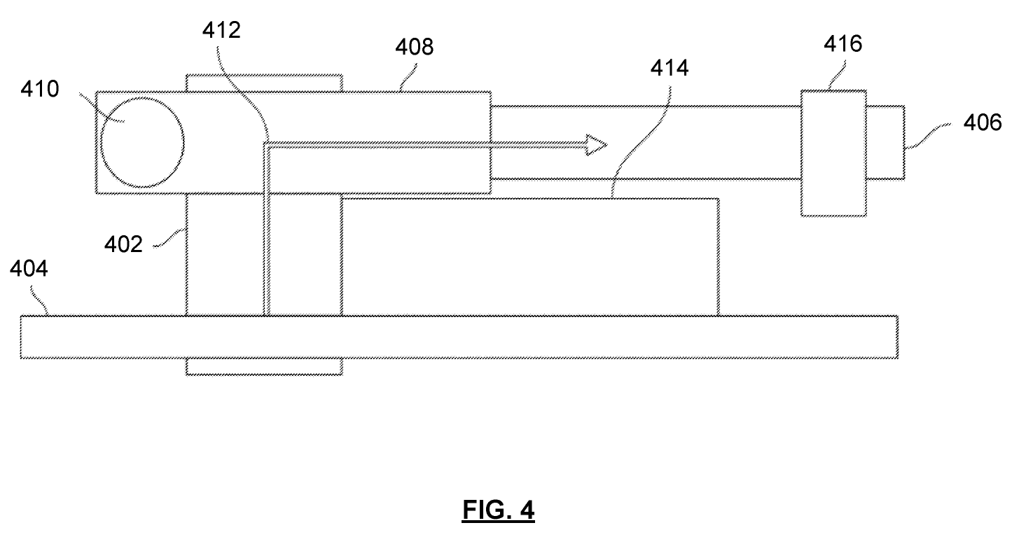

FIG. 4 is side view of an example terminal post 402 of a vehicle electrical system. As shown in FIG. 4, the terminal post 402 may extend from an electrical component 404, such as a battery or a printed circuit board. A cable 406 is attached to the terminal post 402 via a clamp 408 and bolt 410. A current 412 flows from the electrical component 404 through the terminal post 402 and into the cable 406.

Sensor area 414 shows a strong field area in which a current sensor of an arc fault protection device can be placed. In various example embodiments, a current sensor suitable for placement in sensor area 414 includes a coil-based current sensor or a point field detector. Switch area 416 is a location at which the switch of an arc fault protection device may be placed. The location of the switch (switch area 416) may be “downstream” of the location of the current sensor (sensor area 414).

In some examples, a low voltage bus may have a high frequency ripple (e.g., five kHz or more or less), based on noise from a high voltage bus. The load may be a resistive load, which may be supplied by a fixed voltage source, and the circuits may include one or more power converters, such as buck converters having different bandwidths.

Some example embodiments may execute the arc detection algorithm without using Fast Fourier Transform (FFT) analysis, leading to less computation and faster arc detection. Edge detection algorithms may use up-count modes to avoid false resets in some implementations, and the load current fall rate may not be arbitrary.

In some examples, the vehicle control module may be configured to compare a signature of the sampled current to stored load transient signatures (such as a high frequency load pattern, which may include a motor torque event or motor braking event), where the system will know that changes in current at the load are likely due to electrical system transients, and not an arc event. In these situations, the arc detection and electronic fuse closing may be inhibited, to avoid falsely opening the fuse for transient conditions that are not actually arc events.

In some examples, the vehicle control module may be configured to determine whether the load is faulty, or experiencing abnormal operation or a fault condition. If so, control may inhibit or prevent the arc detection and electronic fuse opening, to avoid falsely opening the fuse for faulty load conditions that are not actually arc events.

In some examples, the electrical system may include multiple electrical loads, and the vehicle control module may be configured to sweep the current signatures of the multiple electrical loads to determine whether they are all experiencing a common transient signal signature (such as effects of motor braking or torque events on the whole electrical system). If so, control may inhibit or prevent the arc detection and electronic fuse opening, to avoid falsely opening the fuse for transient events that are common across multiple electrical loads.

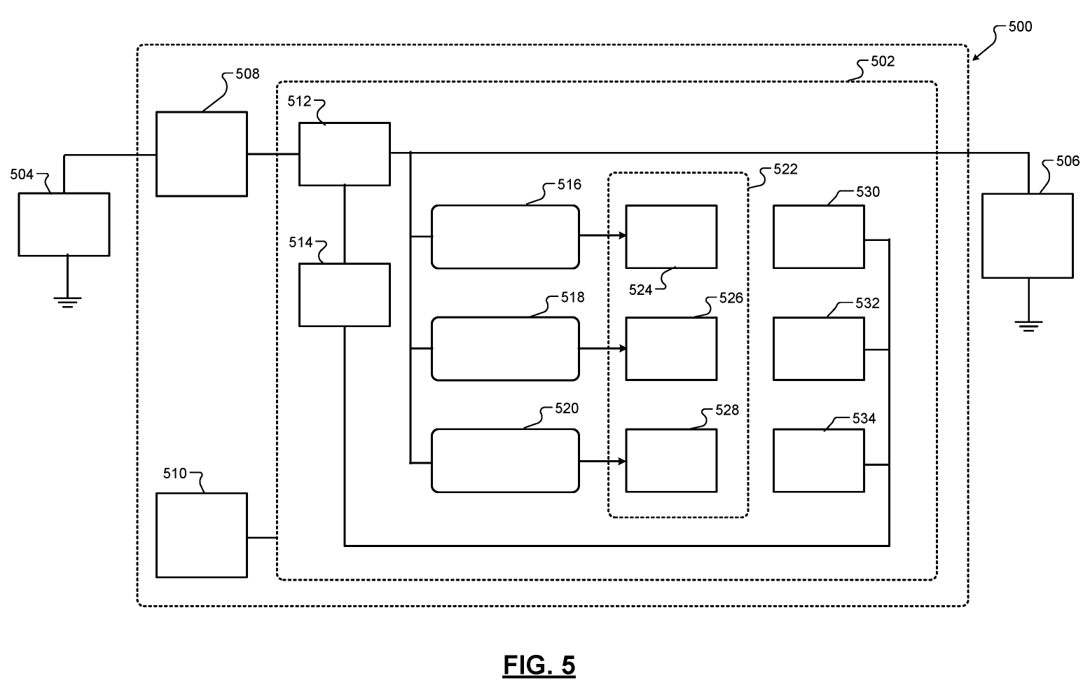

FIG. 5 is a block diagram of an example power distribution circuit 500 in a vehicle including an electronic switch for arc fault protection. As shown in FIG. 5, the power distribution circuit 500 may include an electronic fuse 502 coupled to supply power from the vehicle battery 504 to the vehicle electrical load 506. An input protection and fault isolation circuit 508 may be coupled between the vehicle battery 504 and a field-effect transistor 512 of the electronic fuse 502.

The electronic fuse 502 may include control logic 514 configured to control opening of the field-effect transistor 512 in response to detection of an onset of an arc condition. For example, a first time period edge rate detection 516 may be configured to detect changes in current from a steady-state value that exceed a specified threshold (such as dropping more than two Amps), on a first periodic basis (e.g., sampling the current every one nanosecond). Each detection event exceeding the specified threshold on the first periodic basis may be used to increment a first period count 524.

A second time period edge rate detection 518 may be configured to detect changes in current from a steady-state value that exceed a specified threshold (such as dropping more than two Amps), on a second periodic basis (e.g., sampling the current every ten nanoseconds). Each detection event exceeding the specified threshold on the second periodic basis may be used to increment a second period count 526.

A third time period edge rate detection 520 may be configured to detect changes in current from a steady-state value that exceed a specified threshold (such as dropping more than two Amps), on a third periodic basis (e.g., sampling the current every one-Hundred nanoseconds). Each detection event exceeding the specified threshold on the third periodic basis may be used to increment a third period count 528. Although FIG. 5 illustrate three example sampling periods, other example embodiments may use more or less sampling periods, longer or shorter sampling periods, different current change thresholds, etc.

The histogram counts 522 may be compared with count value thresholds to determine whether an onset of an arc event has been detected. For example, the first period count 524 may be compared against a one nanosecond signature template 530 indicative of a current signal signature at the onset of an arc. The second period count 526 may be compared against a ten-nanosecond signature template 532 indicative of a current signal signature at the onset of an arc. The third period count 528 may be compared against a one hundred nanosecond signature template 532 indicative of a current signal signature at the onset of an arc.

If any of the one nanosecond signature template 530, the ten-nanosecond signature template 532, or the one hundred nanosecond signature template 534 are met, the control logic 514 may be configured to open the field-effect transistor 512 to mitigate or prevent an arc event. In some example embodiments, different combinations of the one nanosecond signature template 530, the ten-nanosecond signature template 532, and the one hundred nanosecond signature template 534 may be required to indicate an onset of an arc event for the control logic 514 to turn off the field-effect transistor 512. A processor such as a microcontroller unit 510 may be coupled to control the electronic fuse 502 and may be part of the vehicle control module.

In some examples, one or more arc detection devices as described herein may be distributed throughout the vehicle power delivery system, leading to greater arc detection coverage and quicker response times to mitigate arcs. With appropriate configuration, other known events of rapid current increases, such as motor braking or torque events, could be masked out in order to eliminate false-positives.

For example, in the event of a known load (e.g., a motor) having a known state (e.g., power up) that would create high-frequency current signals on the power bus, one or more options may be implemented (independently or in combination) to mask out these known events:

In one example, time based blanking may be used to inhibit arc detection for a specified time period at the start-up phase of an electric motor. As another example, blanking may include a change to the event signature that removes events corresponding to the known edge rates during the event detection.

In various implementations, a higher level retry algorithm may be implemented in the case of a failure, to mature the fault and ensure that it was not a false positive. This could be combined with other, known system states and monitoring signals, such as a crash detection signal.

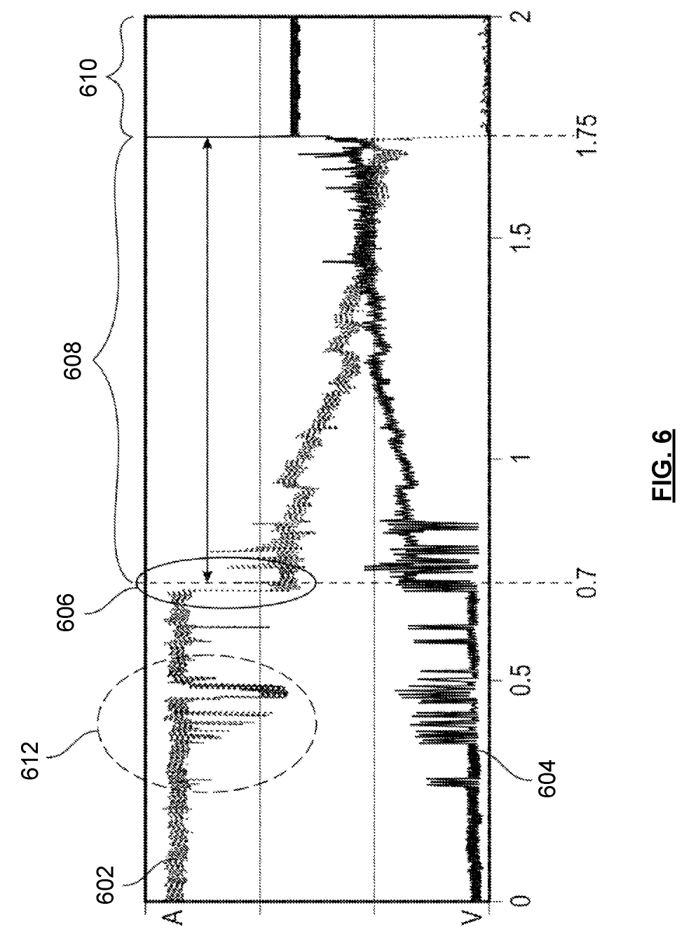

FIG. 6 is a graph illustrating an example electrical signal of an arc fault in a vehicle electrical system. In the example of FIG. 6, time is shown in seconds (s) along the abscissa and current, and voltage are shown along the ordinate axis. The graph shows both current 602 and a corresponding voltage 604. The current 602 may be measured via a current sensor. As seen by the current 602, the arc fault may have three distinct phases: a precursor phase 606, an arc flash phase 608 and an arc extinction phase 610.

The precursor phase 606 (shown in FIG. 6 at about t=0.7 seconds) is a relatively short phase, lasting only a few milliseconds. The precursor phase 606 may be characterized by the current 602 experiencing a sudden current drop that exceeds a given threshold. This current drop corresponds to an increase in voltage. The arc flash phase 608 can last up to several seconds. In FIG. 6 , the arc flash phase 608 is shown from about t=0.7 seconds to about t=1.75 seconds.

During the arc flash phase 608, the current may arc outside of the circuit. The current 602 may be characterized by high-frequency, low amplitude variations in magnitude over time. The arc extinction phase 610 occurs once the current drops to zero, thereby ending the arc flash.

As can be seen in FIG. 6, the precursor phase 606 may be indicated by the occurrence of a sudden current drop. It is noted however that the occurrence of a current drop does not necessarily indicate the onset of an arc flash phase. For example, in FIG. 6, a false precursor 612 occurs at about t=0.5 seconds.

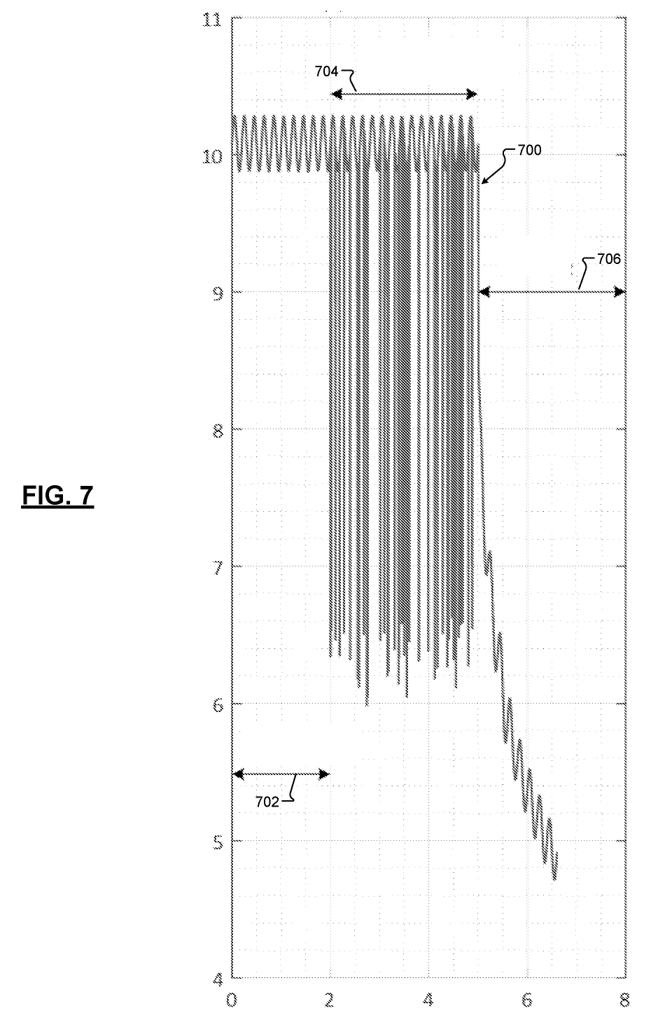

FIG. 7 is a graph illustrating another example electrical signal of an arc fault in a vehicle electrical system. In the example of FIG. 7, a vehicle electrical load may have a steady-state current of about ten Amps. This is shown as the normal period 702 in FIG. 7.

At the onset of an arc event, the current may drop beyond a threshold value, prior to the full arc occurring. In FIG. 7, an arc formation period 704 shows the current dropping three to four Amps from the steady-state value of ten Amps, and returning to the steady-state value, at a high frequency.

After the arc formation period 704, the current drops more significantly with less fluctuation during the full arc period 706. Some example embodiments herein use edge detection circuits to detect the high frequency current fluctuation during the arc formation period 704, to indicate onset of the arc and open a switch prior to the full arc period 706 to mitigate the arc.

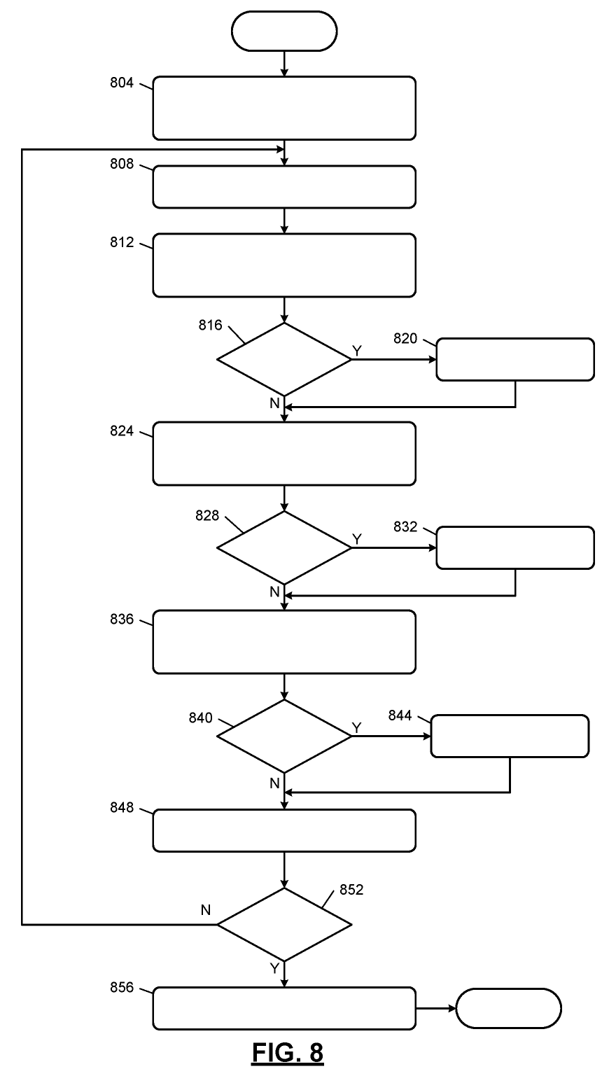

FIG. 8 is a flowchart depicting an example process for detecting and mitigating an arc fault in a vehicle. The example process of FIG. 8 may be executed by any suitable control, such as the vehicle control module 20 of FIG. 1. At 804, the process begins by supplying power from a vehicle battery to an electrical load, via a power distribution circuit.

At 808, the vehicle control module is configured to detect a current value through the power distribution circuit, such as via a current sensor. At 812, control compares a change in current to a specified current change threshold value according to a first time period. For example, control may check whether the sensed current has dropped two or more Amps from a steady-state value, at one nanosecond intervals.

At 816, control determines whether the threshold has been reached. If so, control increments a first period count at 820. For example, if control determines that the current has dropped more than, e.g., two Amps, control may increment the one nanosecond count value.

At 824, the vehicle control module is configured to compares a change in current to the specified current change threshold value according to a second time period. This may be the same or a different current change threshold value compared to the threshold used for the first time period. For example, control may check whether the sensed current has dropped two or more Amps from a steady-state value, at ten nanosecond intervals.

At 828, control determines whether the threshold has been reached. If so, control increments a second period count at 832. For example, if control determines that the current has dropped more than, e.g., two Amps, control may increment the ten nanosecond count value.

At 836, the vehicle control module is configured to compares a change in current to the specified current change threshold value according to a third time period. This may be the same or a different current change threshold value compared to the threshold used for the first time period and the second timer period. For example, control may check whether the sensed current has dropped two or more Amps from a steady-state value, at one hundred nanosecond intervals.

At 840, control determines whether the threshold has been reached. If so, control increments a third period count at 844. For example, if control determines that the current has dropped more than, e.g., two Amps, control may increment the one hundred nanosecond count value.

At 852, the vehicle control module is configured to compare the count values to a specified arc onset threshold. For example, control may determine whether the first period count value is greater than four thousand, the second period count value is greater than four hundred, or the third period count value is greater than forty. These values are provided for example only, and various implementations may use any suitable threshold values, which may be calibrated based on different types of arc events in different types of vehicle electrical systems.

In other examples, more or less time periods may be used, with shorter or longer intervals. Using different time periods may allow for detection of arc precursor events that happen on different time scales. The arc onset threshold may include a combination of different values from different sampling periods, exceeding a threshold in only at least one of the sampling periods, count values that combine to meet a specified signal signature, etc.

In some examples, electronic components may be implemented in an automotive power distribution network to detect electrical arcing events, and mitigate any damage that is done to the power distribution network. For example, circuitry within an eFuse device may be configured to detect the pre-cursor signature of an electrical arc in real-time with very low cost, and without requiring a full FFT software algorithm.

When the pre-cursor is detected, the eFuse controller may open the FET, inhibiting or prevent the arc energy from building up over time, and therefore reducing the potential negative impact of an arc event. An example arc pre-cursor detection algorithm may be based on a sudden drop in a current reading over a configurable threshold (e.g., 2A), for a time longer than a configurable threshold (e.g., 5us). This may be followed by high-frequency content in the current waveform, which may be monitored and detected based on histogram counts the configurable count templates.

A local control may be set to dynamically “blank” or “ignore” potential pre-cursor signature detection when a load is known to create a similar electrical signature (e.g., a motor controller applying significant torque or braking). This may include permanent blanking of specific edge rate counters from contributing to detection, for loads known to create those edge rates.

In some examples, vehicle control modules may disable local eFuse control signature blanking when that specific load is diagnosed to be faulty. If the load raises a DTC then an arc becomes much more likely again and blanking should be disabled.

Circuitry within a 48V load/device, for example, may detect abrupt voltage dips relative to a far-away source in the vehicle electrical system. When the arc pre-cursor is detected, a smart load may trigger a signal for the eFuse controller to open the FET, to inhibit or prevent allowing the arc energy from building up over time and thus reducing the potential negative impact of arc event. In various implementations, the vehicle control module may be configured to scan or sweep multiple connected electrical loads at once, to detect a common signature for decoupling purposes (such as transients due to motor events).

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In the figures, the direction of an arrow, as indicated by the arrowhead, generally demonstrates the flow of information (such as data or instructions) that is of interest to the illustration. For example, when element A and element B exchange a variety of information but information transmitted from element A to element B is relevant to the illustration, the arrow may point from element A to element B. This unidirectional arrow does not imply that no other information is transmitted from element B to element A. Further, for information sent from element A to element B, element B may send requests for, or receipt acknowledgements of, the information to element A.

In this application, including the definitions below, the term “module” or the term “controller” may be replaced with the term “circuit.” The term “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components that provide the described functionality; or a combination of some or all of the above, such as in a system-on-chip.

The module may include one or more interface circuits. In some examples, the interface circuits may include wired or wireless interfaces that are connected to a local area network (LAN), the Internet, a wide area network (WAN), or combinations thereof. The functionality of any given module of the present disclosure may be distributed among multiple modules that are connected via interface circuits. For example, multiple modules may allow load balancing. In a further example, a server (also known as remote, or cloud) module may accomplish some functionality on behalf of a client module.

The term code, as used above, may include software, firmware, and/or microcode, and may refer to programs, routines, functions, classes, data structures, and/or objects. The term shared processor circuit encompasses a single processor circuit that executes some or all code from multiple modules. The term group processor circuit encompasses a processor circuit that, in combination with additional processor circuits, executes some or all code from one or more modules. References to multiple processor circuits encompass multiple processor circuits on discrete dies, multiple processor circuits on a single die, multiple cores of a single processor circuit, multiple threads of a single processor circuit, or a combination of the above. The term shared memory circuit encompasses a single memory circuit that stores some or all code from multiple modules. The term group memory circuit encompasses a memory circuit that, in combination with additional memories, stores some or all code from one or more modules.

The term memory circuit is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read-only memory circuit), volatile memory circuits (such as a static random access memory circuit or a dynamic random access memory circuit), magnetic storage media (such as an analog or digital magnetic tape or a hard disk drive), and optical storage media (such as a CD, a DVD, or a Blu-ray Disc).

The apparatuses and methods described in this application may be partially or fully implemented by a special purpose computer created by configuring a general purpose computer to execute one or more particular functions embodied in computer programs. The functional blocks, flowchart components, and other elements described above serve as software specifications, which can be translated into the computer programs by the routine work of a skilled technician or programmer.

The computer programs include processor-executable instructions that are stored on at least one non-transitory, tangible computer-readable medium. The computer programs may also include or rely on stored data. The computer programs may encompass a basic input/output system (BIOS) that interacts with hardware of the special purpose computer, device drivers that interact with particular devices of the special purpose computer, one or more operating systems, user applications, background services, background applications, etc.

The computer programs may include: (i) descriptive text to be parsed, such as HTML (hypertext markup language), XML (extensible markup language), or JSON (JavaScript Object Notation) (ii) assembly code, (iii) object code generated from source code by a compiler, (iv) source code for execution by an interpreter, (v) source code for compilation and execution by a just-in-time compiler, etc. As examples only, source code may be written using syntax from languages including C, C++, C#, Objective-C, Swift, Haskell, Go, SQL, R, Lisp, Java®, Fortran, Perl, Pascal, Curl, OCaml, Javascript®, HTML5 (Hypertext Markup Language 5th revision), Ada, ASP (Active Server Pages), PHP (PHP: Hypertext Preprocessor), Scala, Eiffel, Smalltalk, Erlang, Ruby, Flash®, Visual Basic®, Lua, MATLAB, SIMULINK, and Python®.

What is claimed is:

1. An arc fault detection system for vehicles, the arc fault detection system comprising:
at least one vehicle battery;
at least one vehicle electrical load;
a power distribution circuit configured to supply power from the at least one vehicle battery to the at least one vehicle electrical load, the power distribution circuit including at least one switch;
a sensor configured to detect a current value through the power distribution circuit; and
a vehicle control module configured to:
periodically compare a change in the current value to a specified current change threshold value, according to a first time period, and increase a first count value each time the change in the current value exceeds the specified current change threshold value according to the first time period;
periodically compare the change in the current value to the specified current change threshold value, according to a second time period different than the first time period, and increase a second count value each time the change in the current value exceeds the specified current change threshold value according to the second time period;
compare the first count value and the second count value to a specified arc onset threshold indicative of an onset of an arc flash phase of an arc fault; and
open the at least one switch of the power distribution circuit in response to the first count value and the second count value reaching or exceeding the specified arc onset threshold, to mitigate the arc fault.

2. The arc fault detection system of claim 1, wherein the at least one switch comprises a field-effect transistor.

3. The arc fault detection system of claim 2, wherein the vehicle control module is configured to close the field-effect transistor after an end of the arc fault to reset at least a portion of the power distribution circuit.

4. The arc fault detection system of claim 1, wherein the vehicle control module is configured to:
obtain a current signature of the at least one vehicle electrical load;
compare the current signature to a stored transient load event signature indicative of occurrence of a transient power event for the at least one vehicle electrical load; and
inhibit arc fault mitigation, in response to a match between the current signature and the stored transient load event signature.

5. The arc fault detection system of claim 4, wherein the stored transient load event signature corresponds to a high-frequency load pattern.

6. The arc fault detection system of claim 1, wherein the vehicle control module is configured to:
detect a fault condition of the at least one vehicle electrical load; and
inhibit arc fault mitigation, in response to detecting the fault condition of the at least one vehicle electrical load.

7. The arc fault detection system of claim 1, wherein:
multiple electrical loads are each coupled to receive power from the at least one vehicle battery via the power distribution circuit; and
the vehicle control module is configured to:
obtain a current signature for each of the multiple electrical loads; and
inhibit arc fault mitigation, in response to the current signature for each of the multiple electrical loads being a common current signature indicative of a common transient condition across the multiple electrical loads.

8. The arc fault detection system of claim 1, wherein:
the at least one vehicle electrical load comprises a resistive electrical load; and
the specified current change threshold value defines an amount of decrease in the current value from a steady-state current.

9. The arc fault detection system of claim 1, wherein:
the at least one vehicle electrical load receives comprises a power converter; and
the specified current change threshold value defines an amount of increase in the current value from a steady-state current.

10. The arc fault detection system of claim 1, wherein:
the vehicle control module is configured to periodically compare the change in the current value to the specified current change threshold value, according to a third time period different than the first time period and the second time period, and increase a third count value each time the change in the current value exceeds the specified current change threshold value according to the third time period;
comparing includes comparing the first count value, the second count value and the third count value to the specified arc onset threshold; and
opening incudes opening the at least one switch in response to the first count value, the second count value and the third count value reaching or exceeding the specified arc onset threshold.

11. The arc fault detection system of claim 10, wherein:
the first time period is one nanosecond;
the second time period is ten nanoseconds; and
the third time period is one hundred nanoseconds.

12. The arc fault detection system of claim 1, wherein the specified current change threshold value is at least two Amps.

13. The arc fault detection system of claim 1, wherein the at least one vehicle battery is configured to output a voltage of at least twenty Volts.

14. The arc fault detection system of claim 1, wherein the vehicle control module is configured to open the at least one switch without executing a Fast Fourier Transform (FFT) analysis on the current value.

15. A method of arc fault detection system for vehicles, the method comprising:
supplying power from at least one vehicle battery to at least one vehicle electrical load via a power distribution circuit, the power distribution circuit including at least one switch;
detecting, by a current sensor, a current value through the power distribution circuit;
periodically comparing, by a vehicle control module, a change in a current value to a specified current change threshold value, according to a first time period, and increase a first count value each time the change in the current value exceeds the specified current change threshold value according to the first time period;
periodically comparing the change in the current value to the specified current change threshold value, according to a second time period different than the first time period, and increase a second count value each time the change in the current value exceeds the specified current change threshold value according to the second time period;
comparing the first count value and the second count value to a specified arc onset threshold indicative of an onset of an arc flash phase of an arc fault; and
opening the at least one switch of the power distribution circuit in response to the first count value and the second count value reaching or exceeding the specified arc onset threshold, to mitigate the arc fault.

16. The method of claim 15, wherein the at least one switch comprises a field-effect transistor.

17. The method of claim 16, further comprising closing the field-effect transistor after to an end of the arc fault to reset at least a portion of the power distribution circuit.

18. The method of claim 15, further comprising:
obtaining a current signature of the at least one vehicle electrical load;
comparing the current signature to a stored transient load event signature indicative of occurrence of a transient power event for the at least one vehicle electrical load; and
inhibiting arc fault mitigation, in response to a match between the current signature and the stored transient load event signature.

19. The method of claim 18, wherein the stored transient load event signature corresponds to at least one of a motor torque event or a motor braking event.

20. An arc fault detection system for vehicles, the arc fault detection system comprising:
a power distribution circuit configured to supply power from at least one vehicle battery to at least one vehicle electrical load, the power distribution circuit including at least one switch;
a sensor configured to detect a current value through the power distribution circuit; and
a vehicle control module configured to:
periodically compare a change in the current value to a specified current change threshold value, according to a first time period, and increase a first count value each time the change in the current value exceeds the specified current change threshold value according to the first time period;
periodically compare the change in the current value to the specified current change threshold value, according to a second time period different than the first time period, and increase a second count value each time the change in the current value exceeds the specified current change threshold value according to the second time period;
compare the first count value and the second count value to a specified arc onset threshold indicative of an onset of an arc flash phase of an arc fault; and
open the at least one switch of the power distribution circuit in response to the first count value and the second count value reaching or exceeding the specified arc onset threshold, to mitigate the arc fault, without executing a Fast Fourier Transform (FFT) analysis on the current value.
